(19) United States
(12) Patent Application Publication
(10) Pub. No.: US 2006/0244462 A1
(43) Pub. Date: Nov. 2, 2006

(54) System and method for characterizing power on a local area network

(76) Inventors: John C. McCosh, San Diego, CA (US); Danell J. Johnson, Le Mesa, CA (US)

Correspondence Address: WILLIAM J. KOLEGRAFF, 3119 TURNBERRY WAY, JAMUL, CA, 91935, US

(21) Appl. No.: 11/116,085

(22) Filed: Apr. 27, 2005

(51) Int. Cl. G01R 31/08

(52) U.S. Cl. 324/522

(57) ABSTRACT

A tester for characterizing an Ethernet connection is provided. In one example the tester has a connector for coupling to an Ethernet port. The connector has a set of output lines connected to a selector. A controller configures the selector to selectively couple pairs of the output lines to a measurement circuit. Different pairs of output lines are measured to determine which, if any, of the pairs are powered. The tester may also characterize the type of power found. For example, the power may be an “always on” AC or DC power, or provided according to a vendor-specific handshaking sequence. In another example, the power may be compliant with a power standard, such as IEEE802.3af. In characterizing the power according to a particular power implementation, the tester may have to emulate handshaking or other expected responses according to the standard or vendor specification. The tester may also be constructed to characterize the power requirements for a powered Ethernet device. In this case, the tester also has a power source, that under processor control, selectively applies power to the powered Ethernet device. The tester manipulates selected pairs of lines with defined power handshaking to determine which, if any, power standards the device complies with. In one arrangement, the tester is constructed as a hand-held portable device.

### CROSS REFERENCE TO RELATED APPLICATIONS

Not applicable.

### STATEMENT REGARDING FEDERALLY SPONSORED RESEARCH AND DEVELOPMENT

Not applicable.

### REFERENCE TO A COMPUTER LISTING, A TABLE, OR A COMPUTER PROGRAM LISTING COMPACT DISK APPENDIX

Not applicable.

### BACKGROUND

### Field

The present invention relates generally to characterizing power distribution and use on a local area network. More particularly, the present invention relates to a tester for identifying and characterizing power distribution and use on a local area network such as an Ethernet network.

Local area networks have evolved to interconnect local computing resources, as well as provide connectivity to wide area resources. Although several standards exist for implementing a local area network, such as token ring, FDDI, and Arcnet, the Ethernet standard has become widely used. Ethernet is a local area network standard for sharing computing resources. The Ethernet standard has advanced and expanded over time, and is now the most widely used local network access method. Ethernet is a popular network protocol and cabling scheme capable of supporting transfer rates of 10, 100, or 1000 Megabits per second. The Ethernet standard is administered by the IEEE organization in a set of documents identified as 802.03. As technology and functional requirements change, industry and the IEEE advance or amend the specification as needed. Although the Ethernet standard generally sets out cabling requirements, other industry standards and practices have developed. For example, The Telecommunications Industry Association (TIA) manages a cabling standard known as ANSI/TIA.EIA-568B. The 568B standard sets out specifications, installation procedures, and test requirements for cables, patch cords, and other interconnection devices. In a specific example, the 568B standard details the physical and electrical characteristics for UTP (unshielded twisted pair) installed at different channel lengths and configured for different transfer rates. In one configuration, the Ethernet standard uses twisted-pair wire as a physical layer to interconnect local devices. Twisted-pair wire is relatively inexpensive, and relatively easy to route within a building. Although Ethernet usually operates using 2 pairs of wires, the cable that is distributed throughout the building may have 4 or more pairs of wires. This allows the extra pairs to be used for other purposes. Ethernet standards that can use twisted pair, for example, 10BaseT, 100BaseT, and 1000BaseT, typically have a network device, such as a computer, that has a network interface card. The network interface card couples to the Ethernet network using a cable, which typically connects to an Ethernet wall jack. Often, the wall jack is a standard RJ45 female connector. A section of twisted pair wire connects the wall jack to an Ethernet source port. The source port may be on a computer, but often is at a switch device, router, or hub. A set of switches, routers, hubs, and computers may then be interconnected.

As Ethernet has evolved, new types of devices have come to support the Ethernet standard. For example, Ethernet now supports voice communication using a Voice Over Internet Protocol (VoIP). To use VoIP, an Ethernet enabled handset is attached to the Ethernet wall jack, with voice data packets being routed to another selected Ethernet handset at a known IP address or to a standard handset through a VoIP service provider. To make using these new Ethernet devices easier, Ethernet has been adapted to allow a “powered Ethernet” so that the network cables may also distribute power. The origins of powered Ethernet can be traced back to Voice over Internet Protocol (VOIP) telephone service. VoIP technology allows voice and data transmission utilizing a common wiring plant. VoIP telephone sets required locally provided power for operation usually from an AC adaptor. Locally powered VoIP telephone service is subject to interruption in the event of a power outage. Standard telephone service is not affected by power outages as the telephone system is powered from batteries at the local telephone company. To address the need of un-interrupted VoIP telephone service, VoIP hardware vendors designed a method of powering VoIP telephone sets over the standard Ethernet twisted pairs. In one example, the powering method was simply to apply AC or DC power to a wire pair, and leave the power “on” continuously. Not only could this “always-on” configuration be dangerous to network technicians, but a port had to be specifically configured for the cooperating device. If a different device was connected to such a port, the device, or the network itself, could be damaged. Alternatively, some hardware vendors developed their own vendor-specific powered Ethernet solutions that required the power source to complete a handshake sequence with a device prior to activating power. In this way, the vendor-specific solution assured that a power-compatible device was connected to a port before power was activated. Some of these vendor-specific solutions were implemented while formal industry wide standards were developed and ratified, while some continue to be used and developed for specific applications. In one example, Cisco ® has a widely implemented and used vendor-specific power solution.

The IEEE standard for powered Ethernet, IEEE 802.3af, was ratified in 2004. The standard addresses the issues with providing a voltage source over existing Ethernet wiring configurations. The standard allows the sourcing of up to 12.95 Watts to the powered device. The ratified IEEE 802.3af Powered Ethernet standard has opened the door to many new products beyond its VoIP beginnings. For example, many wireless network access points use powered Ethernet. The wireless network access point is usually mounted in or above the ceiling in the center of the room where 115 V outlets are not available. Using a Powered Ethernet wireless access point eliminates the need for a 115 volt outlet. Ethernet based security cameras are another use for powered Ethernet. The typical wiring for 10Base-T and 100 Base-T Ethernet is a cable containing four twisted wire pairs. The first wire pair is used for transmit data, the second pair is used for the receive data. The two remaining wire pairs are unused. The IEEE 802.3af standard allows power to be supplied using the two unused wire pairs.

Applying power to the unused wire pairs allows the use of existing Ethernet devices, switches, hubs, routers, etc., when upgrading to powered Ethernet. A midspan power injector is a device that is placed in between the Ethernet switch or hub and the powered device. The midspan injector typically supplies power utilizing the two unused Ethernet wire pairs, although the standard supports other wire pairs as well. However, in some wiring installations, the four pair Ethernet cable is used to provide two Ethernet connections. The IEEE standard for 1000 Base-T Ethernet over copper also uses all four of the wire pairs in the Ethernet cable. In both cases, no spare wire pairs are available for powering a remote device. The IEEE powered Ethernet standard addresses these installations by providing phantom power over the first and second wire pairs.

Powered Ethernet places additional burdens on the wiring plant. Cabling that passes Ethernet data may not be suitable for Powered Ethernet due to excessive loop resistance. The cables loop resistance limits the amount of power that can be delivered to the load device. Excessive loop resistance can be caused by an open wire or a bad cable termination or punch down or excessive cable length. When a powered Ethernet device is plugged into the network and it does not function properly, the user needs a simple fast tester to pinpoint the problem which could be associated with the device itself, the Ethernet cabling, or the powered Ethernet switch, Hub or midspan power injector.

Therefore there is a need for a device and process to identify and characterize the power capabilities of an Ethernet connection.

### SUMMARY

Briefly, the present invention provides a tester for characterizing an Ethernet connection. In one example the tester has a connector for coupling to an Ethernet port. The connector has a set of output lines connected to a selector. A controller configures the selector to selectively couple pairs of the output lines to a measurement circuit. Different pairs of output lines are measured to determine which, if any, of the pairs are powered. The tester may also characterize the type of power found. For example, the power may be an “always on” AC or DC power, or provided according to a vendor-specific handshaking sequence. In another example, the power may be compliant with a power standard, such as IEEE802.3af. In characterizing the power according to a particular power implementation, the tester may have to emulate handshaking or other expected responses according to the standard or vendor specification. The tester may also be constructed to characterize the power requirements for a powered Ethernet device. In this case, the tester also has a power source, that under processor control, selectively applies power to the powered Ethernet device. The tester manipulates selected pairs of lines with defined power handshaking to determine which, if any, power standards the device complies with. In one arrangement, the tester is constructed as a hand-held portable device.

In a more specific example, the tester also has a load, which may be adjusted by the controller. By making measurements at different loads, the test may determine the loop resistance from an Ethernet wall jack to the power source at a switch or midspan injector. By making an additional measurement at another load value, the tester may be enabled to determine if a power fault is in the link form the wall jack to the power source, of if the fault is at the power source itself. Also, by applying the power to the adjustable load for only a brief time while taking the power measurement, the size and power ratings for tester components may be reduced. Then, the tester may apply power to the device and determine its power demands.

These and other features of the present invention will become apparent from a reading of the following description, and may be realized by means of the instrumentalities and combinations particularly pointed out in the appended claims.

### BRIEF DESCRIPTION OF THE DRAWINGS

The drawings constitute a part of this specification and include exemplary embodiments of the invention, which may be embodied in various forms. It is to be understood that in some instances various aspects of the invention may be shown exaggerated or enlarged to facilitate an understanding of the invention.

FIG. 1 is a block diagram of a powered Ethernet tester in accordance with the present invention.

FIG. 2A is a flowchart of a method for characterizing a powered Ethernet port in accordance with the present invention.

FIG. 2B is a flowchart of a method for characterizing a powered Ethernet port in accordance with the present invention.

FIG. 3 is a flowchart of a method for characterizing a powered Ethernet port in accordance with the present invention.

FIG. 4 is a flowchart of a method for characterizing a power fault in accordance with the present invention.

FIG. 5A is a flowchart of a method for characterizing a power fault in accordance with the present invention.

FIG. 5B is a flowchart of a loading process in accordance with the present invention.

FIG. 6 is a block diagram illustrating the determination of loop resistance in accordance with the present invention.

FIG. 7 is a block diagram of a powered Ethernet tester in accordance with the present invention.

FIG. 8 is a block diagram of a powered Ethernet tester in accordance with the present invention.

FIG. 9 is a block diagram of a powered Ethernet tester in accordance with the present invention.

FIG. 10 is a flowchart of a process to characterize a powered Ethernet device in accordance with the present invention.

### DETAILED DESCRIPTION

Detailed descriptions of examples of the invention are provided herein. It is to be understood, however, that the present invention may be exemplified in various forms. Therefore, the specific details disclosed herein are not to be interpreted as limiting, but rather as a representative basis for teaching one skilled in the art how to employ the present invention in virtually any detailed system, structure, or manner.

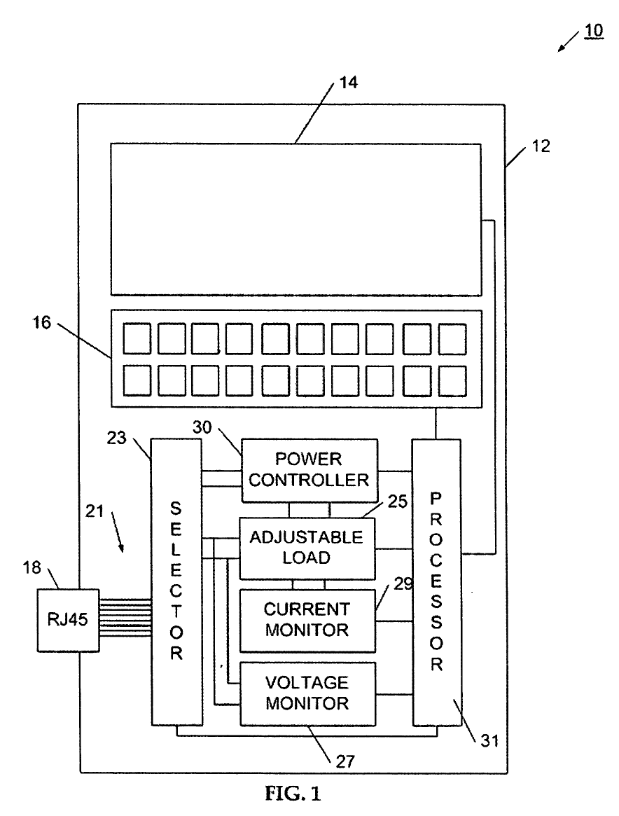

Referring now to FIG. 1, a network power tester 10 is illustrated. Power tester 10 may be used i) to determine if a network connection is configured to provide power, and ii) to characterize the quality of the supplied power. In one example, the power tester 10 is constructed to characterize an Ethernet connection. Although the power tester 10 is discussed with reference to Ethernet, it will be appreciated that other local area network arrangements may be used. When the power tester 10 is connected to an Ethernet jack, the power tester 10 determines if an “always-on” power source is present. More particularly, the power tester 10 measures wires pairs for the presence of either an AC or DC power source. If such an always-on power source is found, then the general characteristics of the power source are presented to the user. The power tester 10 also determines if the Ethernet jack is capable of supporting any of the widely used Ethernet power implementations. Unlike the “always-on” power source, if power is provided by one of the other implementations, the power is not activated until the power source has confirmed that a proper Ethernet powered device is connected to the Ethernet jack. Accordingly, the power tester 10 performs the necessary steps to configure itself according to each of the power implementations, and then determines if an Ethernet power source has been activated. The power implementation may be a vendor-specific solution, such as one from Cisco ®, or the power implementation may be according to a standard, such as IEEE802.3af. If a power source is found, the quality of the power is generally characterized. In one specific example, if a fault is found in the power quality, the power tester 10 assists in identifying if the fault is at the power source or in the connection from the power source to the power tester 10. Advantageously, power tester 10 enables an installer or network technician to safely and efficiently determine if a network connection is powered, and if so, then to characterize the power quality.

Power tester 10 generally comprises a housing 12, which is sized for ease of portability. Although power tester 10 is generally shown to be sized for handheld use, it will be appreciated that the functionality of the power tester may be designed into different types of housings. For example, the housing could be made smaller or larger to accommodate application specific needs. Further, the functionality of the power tester may be in more than one physical housing. The power tester 10 also has a display 14 for displaying instructions and results to a user. A user instructs the power tester 10 using control inputs 16. The control inputs may be for example, keyboards, keypads, switches, rotary switches, or soft keys which interact with associated menus on the display 14. It will be appreciated that other types of inputs may be used. The power tester 10 may also have audible alerts, for audibly warning a user that power has been found, or LED's or lamps for providing visual alerts. For example, some Ethernet ports have an always-on power. Such a condition may cause safety concerns for a technician or equipment. Accordingly, an audible or visual alert may assist in more effectively notifying the operator or technician of the presence of a powered and active wire pair.

The housing 12 also has a network connector 18 for coupling to a network jack. Typically, Ethernet connects using a standard RJ-45 connector. However, it will be understood that other connectors could be used. For example, some network connections are made using standard telephone connectors, while others may require a patch cable. The network connector 18 separates the network lines into separate lines 21 which are received into a selector 23. The selector 23 operates under control of a processor 31, which allows the selector to switch specific lines for further processing. For example, the processor 31 may select pairs of the input lines to measure for an always-on power. This power may be identified and then characterized by a voltage monitor 27 or a current monitor 29. It will be appreciated that other types of monitoring circuitry may be used. Also, to facilitate identification of other power implementations and for determining quality of power, an adjustable load 25 may be provided. Finally, the power tester 10 has a power controller 30. The power controller 30 is configured to emulate specific power implementations. For example, the power controller 30 may be configured to emulate the IEEE802.3af mid span power standard, the IEEE802.3af phantom power standard, or a vendor-specific implementation such as a Cisco® Ethernet power solution. It will be appreciated that the power controller 30 may be provided in a single device, or it may require multiple devices.

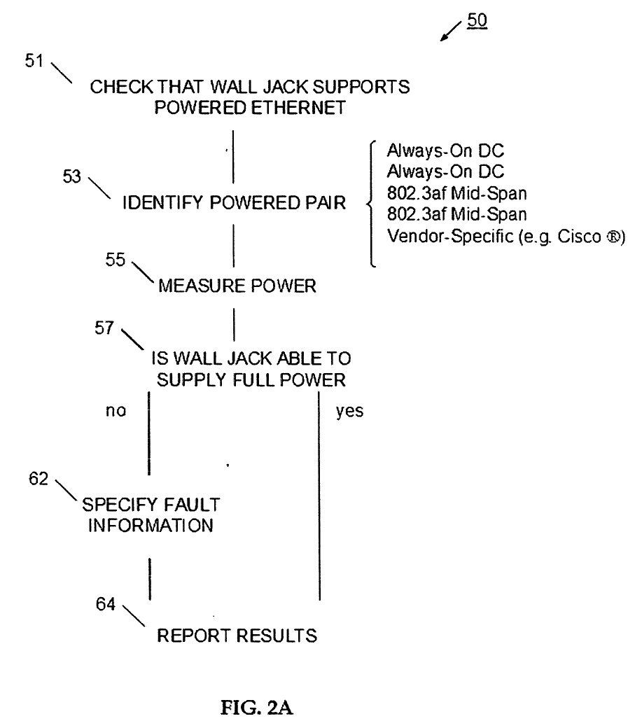

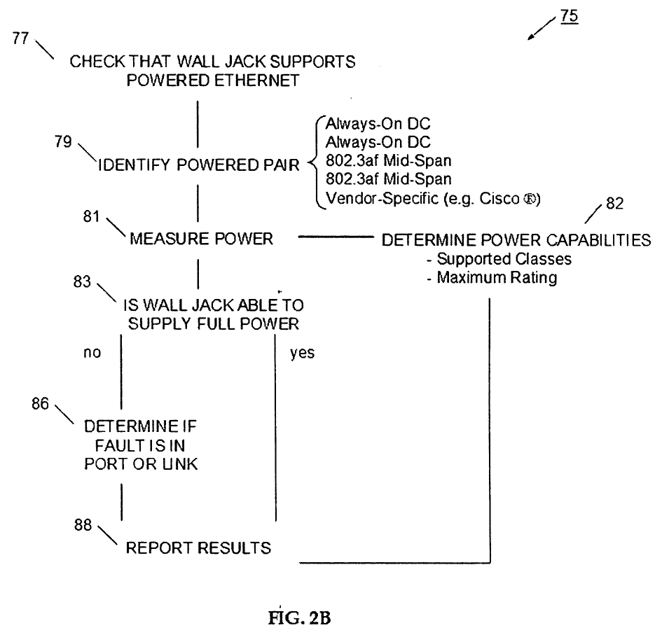

Referring now to FIG. 2a, a method of characterizing a network connection is illustrated. Method 50 uses a power tester to first identify and then characterize power on an Ethernet connection. As shown in block 51, the device first identifies if the Ethernet port at a wall jack is capable of providing power. More particularly, as shown in block 53, determines if any wire pair has an always-on DC or AC power, and then determines if wire pairs associated with any power implementation are powered according to that power implementation. Generally, Ethernet has three widely installed power implementations: IEEE802.3af mid span; IEEE802.3af phantom; or Cisco® vendor-specific power. It will be appreciated that other power implementations may be substituted, and that power implementations are likely to evolve over time. These newer power implementations may be readily incorporated into the method and tester described.

Once the power tester has identified a pair of powered wires, the tester measures the power on those wires as shown in block 55. The tester then determines if the pair of wires is able to support a full power load as shown in block 57. If the connection is able to supply full power, then that result is displayed to the user as shown in block 64. However, if the wires are not able to supply full power, then the power tester performs additional steps to assist in identifying where the power fault may occur. For example, the power tester may assist in determining if the fault is in the port power source, or if the fault is in the link from the power source to the power tester. When the tester has determined the likely location of the fault, that information is displayed to the user as shown in block 64.

Referring now to FIG. 2b, a method of characterizing a network connection is illustrated. Method 75 has a network tester that first checks if an Ethernet wall jack supports powered Ethernet as shown in block 77. More particularly, the tester identifies any pair of wires that are powered either by an always-on power or according to a power implementation as shown in block 79. Once a powered pair is identified, the power quality of that pair is determined as shown in block 81. Depending on which implementation the wire pair supports, the power tester may determine which classes of power supported, as well as a maximum power rating. For example, the IEEE802.3af standard identifies multiple classes of power, with each class having a power rating range. This information may be important as particular devices may require a certain class of power to properly operate. It therefore may be important to determine that the Ethernet jack supports the required class, as well as knowing its maximum power rating. If this information is determined for the operative power standard, the class and maximum rating are displayed to the user as shown in block 88. The power tester determines if the Ethernet wall jack is able to provide full power to a connected device as shown in block 83. If so, that result is reported to the user in block 88. However, if there is a fault which is causing poor power characteristics, then the power tester may further determine if the fault is in the power source or in the connection from the power source to the power tester as shown in block 86. Once the power tester has identified the likely location of the fault, that result is reported to the user in block 88.

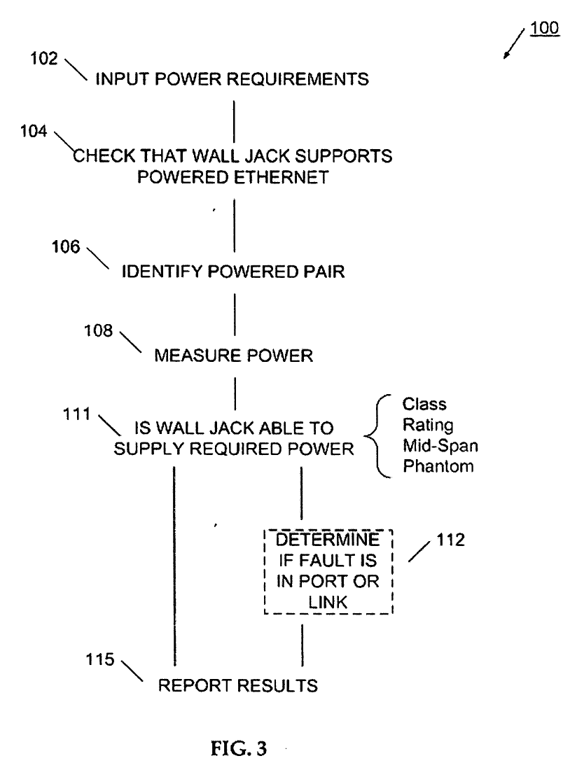

Referring now to FIG. 3, a method of characterizing a network connection is shown. Method 100 allows a user to input device power characteristics as shown in block 102. For example, a powered Ethernet phone device may have specific power requirements to properly operate. It will be understood that these power requirements may be set and adjusted by a user, or may be predefined in the power tester. By predefining the power requirements in the tester, a more compact power tester may be constructed. For example, a small network tester may be constructed for providing a simple pass-fail indication as to whether a port properly supports a specific power need. In this way, an installer may readily confirm that an Ethernet port supports a particular device prior to connecting the device to the Ethernet port. The network tester checks that the wall jack supports a powered Ethernet as shown in block 104. As part of this process, the power tester identifies the particular wire pair having power as shown block 106, and then initiates a power measurement on that pair as shown in block 108. The power tester determines if the wall jack is able to supply the required power, which may include identifying the power's class, rating, and identifying if it is mid span, phantom, or Cisco® compliant. The results of the test may then be reported to the operator or technician as shown in block 115. In one example, the result is displayed as a simple pass-fail indication using an LED, or an audible alert. If the wall jack is powered but is not able to supply full power, then the power tester may optionally determine if the fault is at the port or in the link from the network to the computer. Again, once the network power tester has identified the likely location of the fault, that result may be displayed to the operator or technician, by using an LED light or an audible alert. In this way, method 100 is particularly well-suited for a compact power tester performing a limited power test.

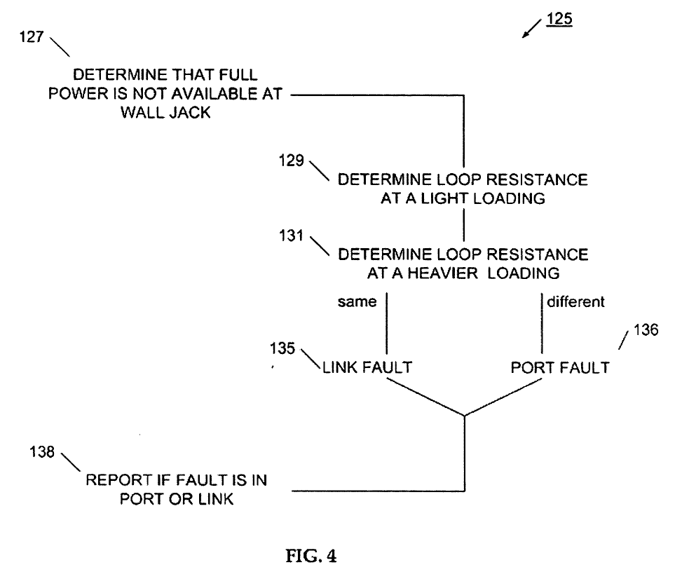

Referring now to FIG. 4, a method of determining the location of a power fault is illustrated. Method 125 uses a power tester to determine that full power is not available at a particular Ethernet wall jack as shown in block 127. The power tester has an adjustable load, and an associated measurement circuits. The tester first determines the loop resistance using a light load as shown in block 129. Then, the power tester determines the loop resistance at a heavier loading as shown in block 171. The loop resistance at light loading is compared to the loop resistance at heavier loading, and if the numbers are substantially the same, the unit determines that the fault is likely in the link as shown in block 135. However, if the loop resistance at light loading is different from the loop resistance at heavier loading, then the unit determines that the fault is likely at the power port source as shown in block 136. The likely location of the fault is then reported to the operator or technician as shown in block 138.

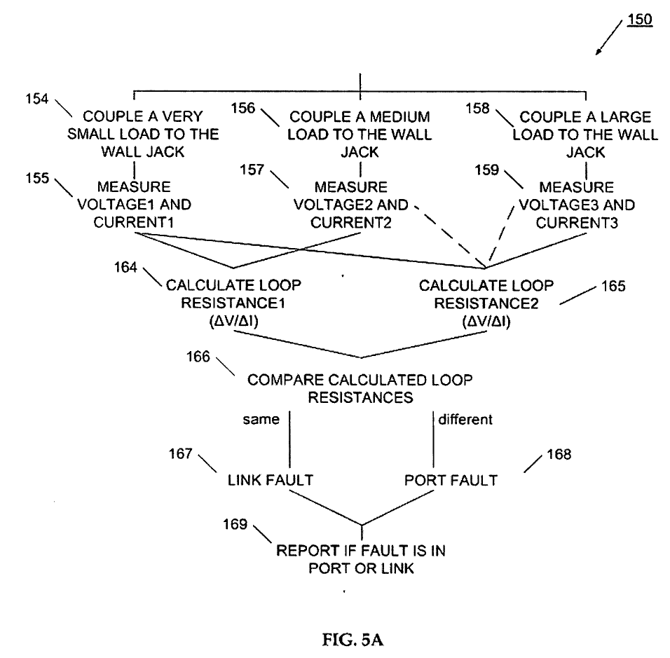

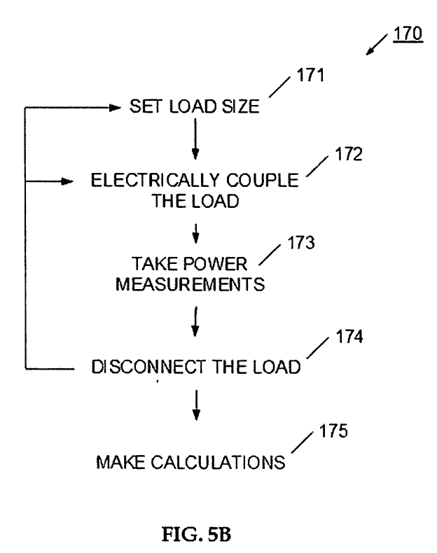

Referring now to FIG. 5a, a method for determining the location of a power fault is illustrated. Method 150 operates on an Ethernet network connection tester. The tester has determined that a fault exists in the delivery of power to the Ethernet wall jack, and now determines if the fault is likely at the power source port, or if the fault is likely in the link from the power source to the wall jack. The power tester has an adjustable power load which may be selectively applied to the powered wire pair. The power tester also has a measurement circuit for measuring the voltage, current, or power at the adjustable load. As shown in block 154, a small load is first applied to the powered wire pair. The voltage and current is measured as shown in block 155. A medium load is then coupled across the powered wire pair as shown in block 156, and the measurement and current again measured. A large load is then coupled across the powered wire pair as shown in block 158, and then the measurement and current again measured as shown in block 159. Using the measurements from the small load and the medium load measurements, a small load loop resistance is first calculated as shown in block 164. Then, using the measurements from the small load and the heavy load, a heavy load loop resistance is calculated as shown in block 165. Alternatively, the heavy load loop resistance could have been calculated by comparing the medium load measurements to the large load measurements. However, increased accuracy may be possible by using the small measurement and the heavy measurement. The light loop resistance and the heavy loop resistance are then compared as shown in block 166. If these loop resistances are substantially similar, then the fault is likely in the link between the power port and the wall jack as shown in block 167. However, if the loop resistances are different, then it is likely that the fault is in the power port as shown in block 168. Once the power tester has determined the likely location of the fault, that location is then displayed or otherwise presented to the technician or operator as shown in block 169.

Referring now to FIG. 5b, a method for determining loop resistance is generally shown. Method 170 operates on a power tester and is useful for determining loop resistance at a particular load size. It will be appreciated that method 170 may be iterated multiple times to increased accuracy, and that the load may be set at different sizes to facilitate additional characterization of the power port. As shown in block 171, the load is set at a known size. The network power tester couples the load across the powered wire pair as shown in block 172. The power tester may wait a short period of time, for example a few milliseconds, for the electrical characteristics to settle. The power tester then takes a power measurement as shown in block 173. Immediately after taking the power measurement, the load is disconnected from the powered wire pair as shown in block 174. In this way, a power measurement may be taken while dissipating minimal power inside the power tester. Accordingly, the power tester may be constructed with components having smaller power ratings, which tend to be less expensive and more compact. In one example, the power test is rapidly repeated at the same load size several times. In this way, the accuracy of the power calculations 175 may be increased, while still dissipating relatively little power. Also, the load size may be changed between measurements. In this way, additional characterization may be done on the power quality. To facilitate the use of the smallest power components in the power tester, the time that power is actively applied to the load is minimized. Further, the time between power measurements may be increased to allow for additional cooling of power tester components.

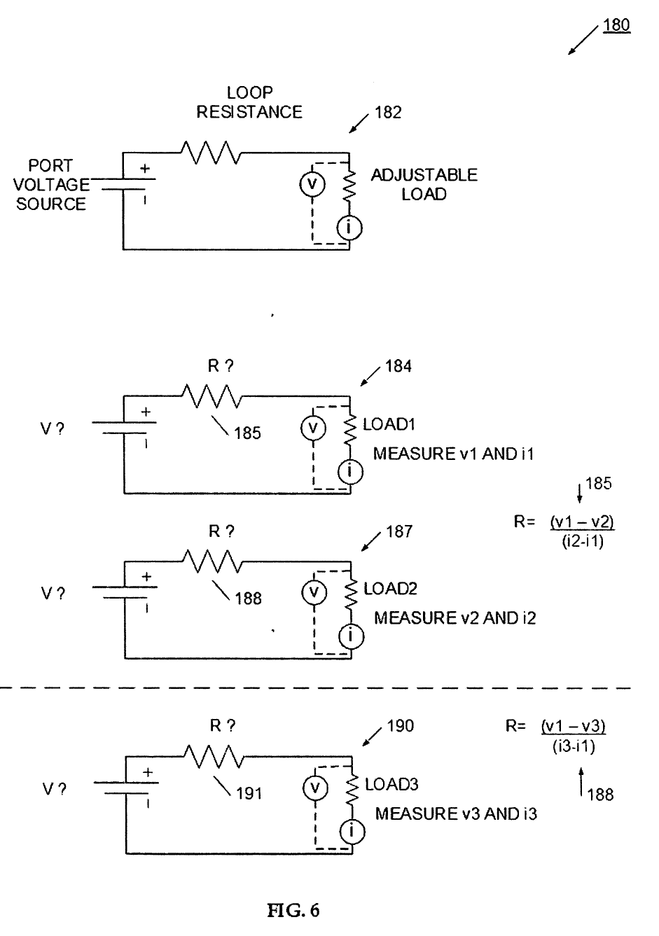

Referring now to FIG. 6, a method of determining loop resistance 180 is illustrated. Method 180 is described with reference to schematic diagrams 182, 184, 187, and 190. These schematic diagrams represent the general electrical characteristics on a powered Ethernet connection. For example, a typical powered Ethernet port has a port voltage source located at the Ethernet switch which provides power on a particular wired pair. The power tester provides an adjustable load and enables a measurement of a voltage and current on that adjustable load. The link between the network tester and the power source port has a particular loop resistance. Since resistance is a substantially linear function, the loop resistance of the link should remain constant irrespective of whether a light, medium, or heavy load is applied. Accordingly, in schematic 182, the loop resistance should remain constant, even under varied loading.

Referring now to schematic 184, it is desirable to determine the value of the loop resistance 185. To do so, a first load is placed across the powered pair and voltage and current measurements taken. As shown in block 187, a second load is placed across the power pair and a second voltage and current measurement taken. Again, it can be generally assumed that the value of resistance 185 is equal to the value of resistance 188, as the value of resistance should not change dependent on the size of the load. In this regard, the value of the loop resistance may be determined according to equation 185. In some uses, simply identifying the magnitude of the loop resistance may be sufficient, and in this case the loop resistance may simply be displayed to the operator or technician. In another example, the range of the loop resistance could be displayed to the technician using LEDs. In this way, the technician would receive a visual indication of either pass-fail, or an indication of which range the loop resistance is in.

To further characterize the power connection, it may be useful to attempt in locating the probable location of a power fault. In this case, schematic 190 shows that a third measurement may be taken. As shown in schematic 190, a third load is applied across the powered pair and associated voltage and current measurements taken. Again, the resistance 191 is assumed to be equal to resistance 188 and resistance 185. Accordingly, the resistance 191 may be calculated according to formula 188. Then, by comparing the resistance calculated in formula 185 to the resistance calculated in formula 188, the likely location of the fault may be identified. More particularly, if the loop resistance calculations are substantially similar, then the fault is likely in the link between the port and the power tester. However, if the calculated loop resistances are different, then the fault is likely in the power source port.

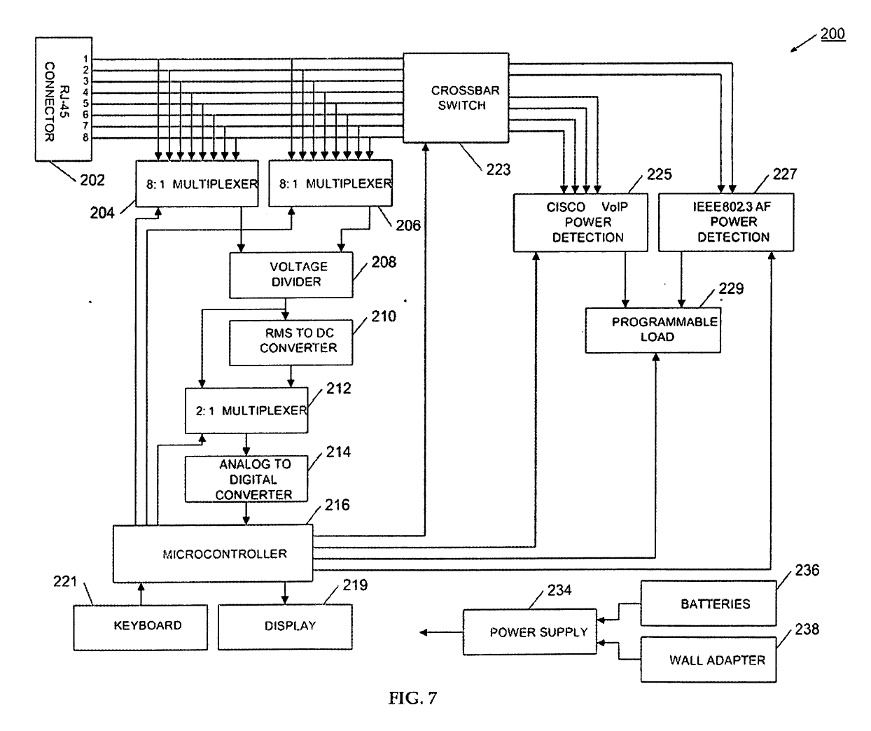

Referring now to FIG. 7, a network power tester is illustrated. Network power tester 200 is configured as an Ethernet power tester. It will be appreciated that other configurations may be used to test other powered network arrangements. Network tester 200 has a connector 202 for coupling to an Ethernet wall jack. Since a typical Ethernet wiring configuration has eight lines, eight output lines extend from the connector 202. It will be appreciated that other numbers of lines may be used according to specific network wiring configurations. A first multiplexer 204 couples to these output lines to select one of the eight output lines and a second multiplexer 206 to select another one of the eight output lines. The two selected lines act as a wire pair for measurement. The multiplexers are under the control of a microcontroller for sequentially selecting different wire pairs. In this way, all potential wire pairs may be measured for the presence of an always-on AC or DC power. In one example of making the power measurements, the microcontroller instructs the multiplexers 204 and 206 to provide a particular wire pair. The wire pair is switched to a voltage divider 208 for scaling the voltage to a more usable level. The scaled voltage is passed to a multiplexer 212 and also through an RMS to DC converter 210. The results from the RMS to DC converter are also passed through multiplexer 212. Each of the voltages may then be measured using the analog to digital converter 214. If a power voltage is found on the line coming directly from the voltage divider, then a DC “always-on” power has been found. If a power voltage is found on the line passing through the RMS to DC converter, then an AC “always-on” power has been identified. If no power voltage is found on either line, then that pair is not a powered pair and the next powered pair may be checked. If all possible powered pairs have been measured, and no AC or DC voltage found, then the tester 200 may report that no “always-on” power is present.

In making the “always-on” determinations, the crossbar switch 223 is configured to present an open circuit to the RJ-45 connector 202. The two 8:1 multiplexers 204 & 206 apply all combinations of RJ-45 connector pins to the voltage divider 208 under control of the microcontroller 216. The voltage divider 208 reduces any voltage present on the RJ-45 connector pins to a voltage level compatible with the analog to digital converter 214 and RMS to DC converter 210. The RMS to DC converter 210 allows the analog to digital converter 214 to accurately measure AC voltages that may be present on the RJ-45 connector pins. The 2:1 multiplexer 212, under control of the microcontroller 216, selects whether an AC or DC voltage measurement is performed. To perform a scan for “always-on” DC voltage the 2:1 multiplexer 212 is configured to apply the voltage divider's output directly to the analog to digital converter 214. The two 8:1 multiplexers 204 & 206 are configured to make the following DC voltage measurements:

| | |
|---|---|
| Pin 2 with respect to (w.r.t.) | Pin 1 |
| Pin 3 w.r.t. | Pin 1 |
| Pin 4 w.r.t. | Pin 1 |
| Pin 5 w.r.t. | Pin 1 |
| Pin 6 w.r.t. | Pin 1 |
| Pin 7 w.r.t. | Pin 1 |
| Pin 8 w.r.t. | Pin 1 |
| Pin 3 w.r.t. | Pin 2 |
| Pin 4 w.r.t. | Pin 2 |
| Pin 5 w.r.t. | Pin 2 |
| Pin 6 w.r.t. | Pin 2 |
| Pin 7 w.r.t. | Pin 2 |
| Pin 8 w.r.t. | Pin 2 |
| Pin 4 w.r.t. | Pin 3 |
| Pin 5 w.r.t. | Pin 3 |
| Pin 6 w.r.t. | Pin 3 |
| Pin 7 w.r.t. | Pin 3 |
| Pin 8 w.r.t. | Pin 3 |
| Pin 5 w.r.t. | Pin 4 |
| Pin 6 w.r.t. | Pin 4 |
| Pin 7 w.r.t. | Pin 4 |
| Pin 8 w.r.t. | Pin 4 |
| Pin 6 w.r.t. | Pin 5 |
| Pin 7 w.r.t. | Pin 5 |
| Pin 8 w.r.t. | Pin 5 |
| Pin 7 w.r.t. | Pin 6 |
| Pin 8 w.r.t. | Pin 6 |
| Pin 8 w.r.t. | Pin 7 |

If any DC voltages are found above a specified threshold level, the “always-on” voltage measurement, including polarity, and RJ-45 connecter pins are displayed. The threshold level is used to qualify the voltage measurement to reject noise that may be present on un-connected RJ-45 connector pins. A similar scan is performed with the 2:1 multiplexer 212 configured for AC voltage measurement to search for “always-on” non-standard AC voltage sources. If any AC voltages are found above a specified threshold level, the “always-on” voltage measurement and RJ-45 connecter pins are displayed. The threshold level is used to qualify the voltage measurement to reject noise that may be present on un-connected RJ-45 connector pins.

If no “always-on” power is found, then the power tester 200 determines if the wall jack supports a handshaking Ethernet power implementation. In one example, the tester 200 is constructed to determine if the connection supports a vendor-specific Cisco implementation or an IEEE802.3af implementation. It will be appreciated that more or fewer power implementations may be selected. The IEEE 802.3af specification allows for power either phantomed on the Ethernet wire pairs 1-2 and 3-6 of the RJ-45 connector, or applied midspan to the unused Ethernet wire pairs 4-5 and 7-8 of the RJ-45 connector. In this regard, the power tester 200 has a power controller that emulates the presence of a powerable Ethernet device. More particularly, the tester 200 has a Cisco® power controller 225 and an IEEE802.3af power controller 227 which may be selectively activated to identify particular power implementations. A crossbar switch 223 is used to select particular wire pairs from the output lines. According to the power implementations, the power must be present on particular specified wire pairs. In this way, the Ethernet power would only be present on particular potential wire pairs. The controller 216 may control the crossbar switch 223 to pass the appropriate wire pair or wire pairs to the IEEE802.3af power controller 227. The controller 216 also activates the power controller 227, so that the power tester 200 emulates a powerable Ethernet device. If the power port is compliant with the IEEE802.3af standard, then the power port will perform the required handshake and verifications according to the standard, and after verification, apply power according to the standard. It will be appreciated that the microcontroller and the power controller 227 may check for the presence of either the mid span IEEE802.3af power or phantom IEEE802.3af power. If no IEEE802.3af compliant power source is found, then the microcontroller may control the crossbar switch to route appropriate wire pairs to the Cisco® power controller 225, and also activate the power controller 225. In this way, the power tester 200 emulates a Cisco® powerable device, and the port, if it supports Cisco® power, will appropriately handshake and activate power according to the vendor-specific requirements.

More particularly, the microcontroller 216 begins searching for phantom 802.3af sources by configuring the crossbar switch 223 to route the RJ-45 connector pins 1-2 and 3-6 to the IEEE 802.3 power detection circuitry 227. The microcontroller 216 also configures the two 8:1 multiplexers 204 & 206 and the 2:1 multiplexer 212 to measure the voltage across RJ-45 connector pins 1 and 3. The programmable load 229 is configured by the microcontroller 216 to sink a current compatible with the user selected IEEE 802.3af class. The amount of current is selected to be at the lower limit of the selected IEEE 802.3af class. The analog to digital converter 214 and associated measurement circuits measures the voltage across RJ-45 connector pins 1 and 3. If the measured voltage is below a specified threshold level, the port under test does not support IEEE 802.3af phantom sources and the tester configures itself to search for voltage on the spare wire pairs. The threshold level is used to qualify the voltage measurement to reject noise that may be present on the RJ-45 connector pins. If the voltage that is measured is above the threshold level, the port supports IEEE 802.3af phantom power. The measured voltage and polarity are stored by the microcontroller 216. The programmable load 229 is then configured for the maximum load current for the selected IEEE 802.3af class and the voltage measurement is repeated. Once the measurement is completed, the programmable load 229 is reconfigured to the lower current to minimize heating in the tester.

The microcontroller 216 then calculates the ports loop resistance by subtracting the high load current voltage measurement from the low load current voltage measurement and dividing the difference by the change in load current (R_{LOOP}=ΔV/ΔI). The microcontroller 216 then displays the measured and calculated port parameters and that the power was phantomed on the Ethernet signal pair. A similar search for IEEE 802.3af power on the spare Ethernet pairs is performed with the crossbar switch 223 reconfigured by the microcontroller to detect midspan power. If IEEE 802.3af port power is found on the spare wire pairs, the loop resistance is calculated and the port parameters are displayed. The display also indicates that the IEEE 802.3af power was found on the spare Ethernet wire pairs indicating mid-span.

If no IEEE 802.3af port phantom or midspan power is found, the microcontroller 216 reconfigures the crossbar switch 223 to route the RJ-45 connector pins to the Cisco® VoIP Power Detection Circuitry 225. The Cisco® VoIP power detection circuitry 225 provides the proper handshaking with Cisco® switches that support Cisco's® vendor specific powered Ethernet. Of course, it will be appreciated that any Cisco® switch that supports the IEEE802af standard will act responsive to the 802.03af handshake. The microcontroller 216 also configures the two 8:1 multiplexers 204 & 206 and the 2:1 multiplexer 212 to measure the voltage across RJ-45 connector pins 1 and 3. The programmable load 229 is configured by the microcontroller 216 to sink a current compatible with Cisco® vendor-specific powered Ethernet. The analog to digital converter 214 measures the voltage across RJ-45 connector pins 1 and 3. If the measured voltage is below a specified threshold level, the port under test does not support Cisco® powered Ethernet. The threshold level is used to qualify the voltage measurement to reject noise that may be present on the RJ-45 connector pins. If the voltage is measured is above the threshold level, the port supports Cisco® powered Ethernet. The measured voltage and polarity are stored by the microcontroller 216. The programmable load 229 is then configured for a higher load and the voltage measurement is repeated. Once the measurement is completed, the programmable load 229 is reconfigured to the lower current to minimize heating in the tester.

The microcontroller 216 then calculates the port's loop resistance by subtracting the high load current voltage measurement from the low load current voltage measurement and dividing the difference by the change in load current (R_{LOOP}=ΔV/ΔI). The microcontroller 216 then displays the measured and calculated port parameters and that the power was provided by a Cisco® powered Ethernet port. The power controllers 225 and 227 cooperate with a programmable load 229 for taking the power measurements. For example, the programmable load may be used to characterize maximum power, determine loop resistance, or determine whether a power fault is in the link or at the power port source. The tester may also determine and display classification for any identified power source. The IEEE 802.3af specification allows for four classes of loads depending on their power dissipation. The multiple load classes are used by the powered port for allocating and distributing power among many powered ports. The IEEE 802.3af port classifications are as follows:

| IEEE 802.3af Class | Load Power Dissipation |
|---|---|
| 0 | 0.44 W to 12.95 W |
| 1 | 0.44 W to 3.84 W |
| 2 | 3.84 W to 6.49 W |
| 3 | 6.49 W to 12.95 W |

Other classes may be added to the IEEE specification as the specification evolves.

The IEEE 802.3af power detection circuitry 227, under control of the microcontroller 216, informs the port under test what class load that the tester will be apply to the port. The user can select what class load the port is tested to. The power tester 200 also has a display 219 for presenting results to the operator or technician, as well as for providing instructions. The operator may provide information to the power tester using the keypad or keyboard 221. It will be understood that other presentation input devices may be used. If the tester 200 is configured as a portable device, the tester will also have batteries powering a power supply 234. For recharging the batteries or operating in a set location, the device may also have an AC wall adapter.

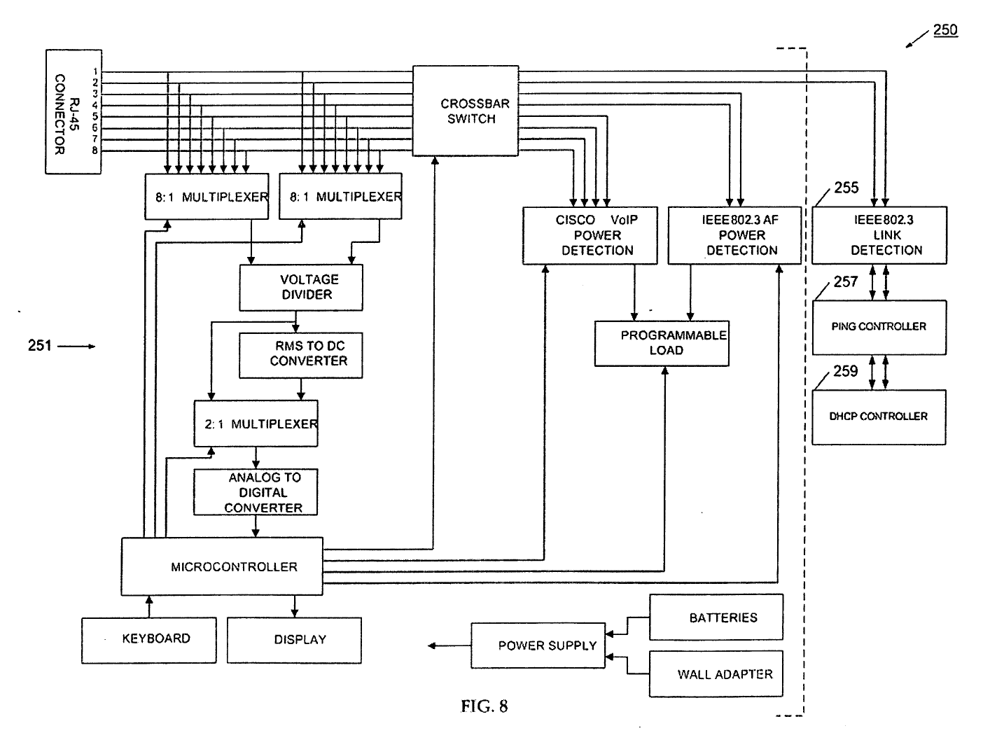

Referring now to FIG. 8, another power tester 250 is described. The Ethernet power tester section 251 is the same as power tester 200 described earlier, so will not be described again. A power tester 250 adds additional testing capabilities for further characterizing the Ethernet connection. For example, block 255 shows that the tester 250 may be arranged with circuitry for establishing a link with the Ethernet switch. By establishing a link, data transmission characteristics may be further characterized. The tester 250 may also have a PING controller 257 for initiating or responding to a typical PING command. In this way, the tester 250 may confirm communication with particular devices on the Ethernet network. Finally, the tester 250 may have a DHCP controller 259. The DHCP controller 259 would assist in confirming that the tester is capable of establishing communication with the DHCP server. The design implementation of the blocks 255, 257, 259 is well known, so will not be described in detail. It will be understood that other network data and electrical tests may be performed to further characterize the connection.

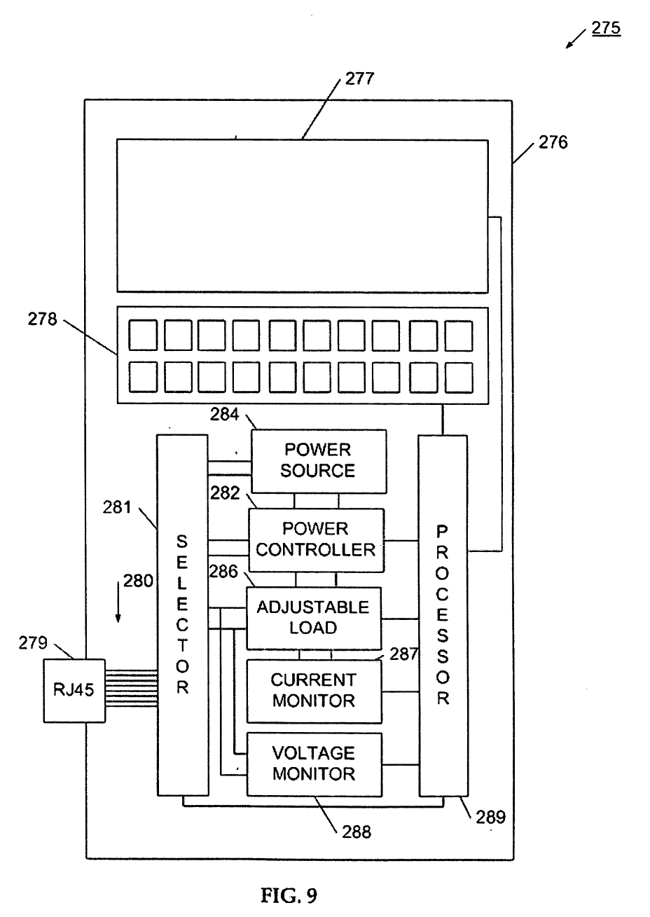

Referring now to FIG. 9, a powered Ethernet tester 275 is illustrated. Tester 275 is constructed to both characterize an Ethernet jack connection, as well as characterize a powerable Ethernet device. Tester 275 has a housing 276 having a display 277 and an input area 278. The input area 278 may include keypads, switches, soft keys, or other input devices. It will be appreciated that the display 277 may be a standard LCD or other display type, and the display devices may include LEDs and audible components. The tester 275 has an RJ-45 Ethernet connector 279 for coupling to either a wall jack or to a powerable Ethernet device. Output lines 280 extend from the connector 279 to a selector 281. It will be understood that the selector 281, for example, may be multiplexers, crossbars, or other selection components. Under control of a processor 289, the selector couples pairs of the output lines for further processing. When operating to characterize an Ethernet wall jack, the power tester 275 operates like tester 10 described with reference to FIG. 1, so this operation will not be described again here. However, tester 275 has extended capability to characterize a powerable Ethernet device. When operating to characterize an Ethernet powerable device, the tester 275 is coupled to a powerable device using connector 279. For example, the powerable device may be a VoIP phone, a network-connected camera, or another Ethernet powerable device. In operation, the processor directs the selector to route appropriately wire pairs to the power controller 282. The processor also activates the power controller 282 to emulate a port power source. The power controller 282 cooperates with a local power source 284 for initiating and performing appropriate handshaking procedures to verify that the connected device supports a power standard, and then for applying the power to verify power characteristics. It will be appreciated that the power source 284 may be part of the power controller 282, or may be separately provided. It will also be understood that the power controller 282 may be a single component, or may be multiple components. For example, the power controller may be a first device for emulating an IEEE802.3af power source, and a second component for emulating a Cisco® power source. The tester 275 may sequentially emulate each of the available power standards to determine if the powered device supports any of the standards. For example, the tester may first check for a response to an IEEE802.3af mid span handshake, and then check for an IEEE802.3af phantom response. Finally the device may check for response to a Cisco® compliant handshake. Since a particular powerable Ethernet device may support more than one standard, all available standards may be identified. Alternatively, the tester may be more limited to check for only particular standards, or may have a preferential list of standards and then stop checking as soon as the most preferred standard is found.

Once one or more standards have been found to be supported by the power able Ethernet device, the device may continue to further characterize the power requirements of the power with the device. In this regard, the processor would use the power controller 282, the power source 284, and the adjustable load 286 to selectively apply combinations of power to the device, and measure its response using the current monitor or voltage monitor 288. In this way, the power requirements of the powered Ethernet device may be determined, and then the class of power identified. In this way, the particular class for the powerable Ethernet device may be displayed, as well as the specific numerical power requirement. By using tester 275, an operator or technician may verify compliance with one or more Ethernet power standards, as well as confirm power classification and power requirements.

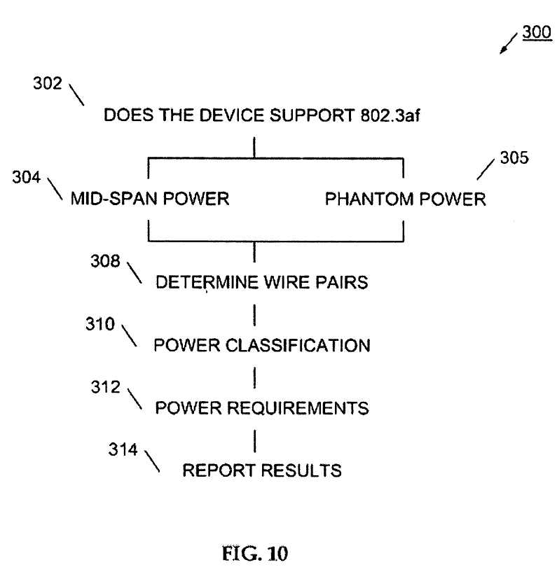

Referring now to FIG. 10, a method for characterizing a powerable Ethernet device is identified. Method 300 uses a power tester to determine if the powerable device supports one of the implementations such as IEEE802.3af. It will be understood that other implementations may be used, such as a vendor-specific implementation. More particularly, the tester uses a power controller to emulate an IEEE802.3af power source, and determines if the powerable device responds according to standard handshaking or response requirements. Once the device has been determined to support one of the IEEE802.3af standards, the tester determines if it supports mid span power 304 or a phantom power 305. A particular powered Ethernet device may support both of the standards. Depending on what standard is supported, the tester will select the proper wire pairs and perform further power characterization as shown in block 308. For example, the tester may confirm the particular power classification for the device 310. In this way, a technician can confirm that a device operates according to its identified classification. Also, devices may be provided as showing a requirement for the highest power classification, irrespective of actual requirements. It may be possible that some devices have lower power requirements, and therefore the technician can identify those devices as having lower classification requirements. Also, the specific numerical power requirement for the device may be determined as shown in block 312. In this way, the particular power requirements may be understood for each device. By knowing specific power requirements, the power utilization may be more efficiently distributed for a particular switch or other power source. Finally, the classification of power requirement results may be presented to the user as reported in block 314. This may include display results, LED indicators, or audible sounds. It will also be appreciated that other characteristic measurements may be made for the power able Ethernet device.

While particular preferred and alternative embodiments of the present intention have been disclosed, it will be apparent to one of ordinary skill in the art that many various modifications and extensions of the above described technology may be implemented using the teaching of this invention described herein. All such modifications and extensions are intended to be included within the true spirit and scope of the invention as discussed in the appended claims.

What is claimed is:

1. A network tester, comprising:
a connector having a set of output lines
a selector coupled to the output lines;
a measurement circuit; and
a processor operating the steps of:
a) configuring the selector to couple a pair of output lines to the measurement circuit;
b) receiving a measurement from the measurement circuit;
c) determining if the selected pair of output lines is a powered pair;
d) repeating steps b and c with a different pair of output lines until a powered pair is found or until all potential pairs have been measured;

2. The network tester according to claim 1, further comprising:
a power controller for emulating a power distribution implementation; and
wherein the configuring step further includes coupling the power controller to the selected pair.

3. The network tester according to claim 1, further comprising:
a load; and
wherein the process further operates the steps of:
coupling the load to the powered pair; and
taking a power measurement while the powered pair is under load.

4. The network tester according to claim 1, further comprising:
an adjustable load; and
wherein the processor further operates the steps of:
setting the adjustable load to a first load;
coupling the first load to the powered pair;
receiving first measurements;
setting the adjustable load to a second load;
coupling the second load to the powered pair;
receiving second measurements; and
using the first and second measurements to calculate a loop resistance.

5. The network tester according to claim 1, further comprising:
an adjustable load; and
wherein the processor further operates the steps of:
setting the adjustable load to a first load;
coupling the first load to the powered pair for only a short period;
instructing the measurement circuit to take a fast measurement while the powered pair is loaded;
setting the adjustable load to a second load;
coupling the second load to the powered pair for only a short period;
instructing the measurement circuit to take a fast measurement while the powered pair is loaded; and
using the first and second measurements to calculate available power from the powered pair.

6. The network tester according to claim 5 wherein each of the short periods is between about 1 millisecond and about 500 milliseconds in duration.

7. The network tester according to claim 3, the processor further operates the steps of:
setting the adjustable load to a third load;
coupling the third load to the powered pair;
receiving third measurements;
using the third measurements and one of the other measurements to calculate a second loop resistance;
comparing the loop resistance to the second loop resistance; and
determining, responsive to the comparing step, if a fault exists in a link from the connector to a port.

8. A method of characterizing a network connection using a network tester, the network tester constructed to connect to a network jack using a network connector, comprising:
a) receiving a set of network lines from the network connector;
b) selecting automatically a pair of lines from the set of network lines;
c) measuring a voltage level across the selected pair; and
d) repeating steps b and c using a different pair of lines until a powered pair is identified.

9. The method according to claim 8, further comprising the step of:
configuring the selected pair of lines to terminate according to a defined power distribution standard prior to measuring the voltage level.

10. The method according to claim 8, wherein the configuring step includes terminating the selected pair of lines with a signature load according to 802.3af.

11. The method according to claim 8, further including the step of determining the polarity of the powered pair.

12. The method according to claim 8, further including the steps of:
loading the powered pair; and
determining available power.

13. A method of characterizing an Ethernet connection using a network tester, the network tester constructed to connect to a jack using an Ethernet connector, comprising:
a) receiving a set of network lines from the Ethernet connector;
b) determining automatically if any pairs of lines from the set of network lines are powered from an always-on power source;
c) applying a signature load across a pair of lines selected from the set of network lines, the signature load selected according to a power distribution implementation;
c) measuring a voltage level across the pair of lines; and
d) displaying, responsive to the measurement, if the pair of lines is powered according to the power distribution implementation.

14. A method of characterizing an Ethernet connection using a network tester, the network tester constructed to connect to a jack using an Ethernet connector, comprising:
providing a powered pair of network lines;
coupling a small load to the powered pair;
taking a first voltage and current measurement;
coupling a medium load to the powered pair;
taking a second voltage and current measurement;
calculating a loop resistance using the first and second measurements;

15. The method according to claim 14, further including the steps of:
coupling a large load to the powered pair;
taking a third voltage and current measurement;
calculating a second loop resistance using two of the measurements;
comparing the loop resistance to the second loop resistance.

16. The method according to claim 15, further including the steps of:
determining that the loop resistance is about the same as the second loop resistance; and
reporting that a link to a network device is good.

17. The method according to claim 15, further including the steps of:
determining that the loop resistance is not about the same as the second loop resistance; and
reporting that a link to a network device is bad.

18. An Ethernet connection tester, comprising:
a housing;
a connector on the housing having a set of output lines
a selector coupled to the output lines;
a measurement circuit; and
a power controller for emulating a power distribution implementation;
a processor operating the steps of:
a) configuring the selector to couple a pair of output lines to the measurement circuit;
b) receiving a measurement from the measurement circuit;
c) determining if the selected pair of output lines is a powered pair;
d) repeating steps b and c with a different pair of output lines until an always-on powered pair is found or until all potential pairs have been measured;
e) configuring the selector to couple a pair of output lines to the measurement circuit;
f) coupling the power controller to the selected pair;
g) determining if the selected pair of output lines is a powered pair conforming to the power distribution implementation;
h) repeating steps e, f, and g with a different pair of output lines until an always-on powered pair is found or until all potential pairs have been measured;

19. The Ethernet connection tester of claim 18, wherein the power controller further includes a signature load according to the power distribution implementation.

20. The Ethernet connection tester of claim 18, further including:
a load; and
wherein the processor further operates the steps of:
coupling the load to the powered pair; and
receiving a power measurement while the powered pair is under load.

21. The Ethernet connection tester according to claim 18, further comprising:
an adjustable load; and
wherein the processor further operates the steps of:
setting the adjustable load to a plurality of load sizes;
receiving a measurements at each load setting;
calculating a loop resistance for a link to a powered Ethernet port.

22. The Ethernet connection tester according to claim 18, further comprising:
an adjustable load; and
wherein the processor further operates the steps of:
setting the adjustable load to at least three load sizes;
receiving a measurements at each load setting;
calculating two loop resistance values using the measurements;
comparing the loop resistance values; and
determining if a fault exists in a link to the powered Ethernet port.

23. The Ethernet connection tester according to claim 18, wherein the housing is sized to be portable and hand held.

24. The Ethernet connection tester according to claim 18 wherein the power distribution implementation is 802.3af midspan.

25. The Ethernet connection tester according to claim 18 wherein the power distribution implementation is 802.3af phantom.

26. The Ethernet connection tester according to claim 18 wherein the power distribution implementation is a vendor-specific implementation.

27. The Ethernet connection tester according to claim 18 further including link circuitry for establishing an Ethernet link with a network device.

28. The Ethernet connection tester according to claim 18 further including ping circuitry for pinging a network device according to established Ethernet processes.

29. The Ethernet connection tester according to claim 18 further including a DHCP controller to establish a DHCP session with a DHCP server.
